(19) United States
(12) Patent Application Publication
(10) Pub. No.: US 2026/0107588 A1
(43) Pub. Date: Apr. 16, 2026

(54) IMAGE SENSOR

(71) Applicant: Samsung Electronics Co., Ltd., Suwon-si (KR)

(72) Inventors: Junoh Kim, Suwon-si (KR); HAEWON LEE, Suwon-si (KR)

(21) Appl. No.: 19/265,180

(22) Filed: Jul. 10, 2025

(30) Foreign Application Priority Data
Oct. 11, 2024 (KR) 10-2024-0138510

(51) Int. Cl. H10F 39/00; H04N 25/62; H04N 25/63

(52) U.S. Cl. CPC H10F 39/802; H04N 25/62; H10F 39/807; H04N 25/63

(57) ABSTRACT

An image sensor includes a substrate that includes a first surface and a second surface facing each other, a plurality of photoelectric conversion elements that is positioned inside the substrate, a floating diffusion region that is adjacent to the first surface and inside the substrate, wherein the floating diffusion region is doped with an impurity, and a first blocking layer positioned in a space between the floating diffusion region and each of the plurality of photoelectric conversion elements in a vertical direction perpendicular to the first surface of the substrate. A thickness, in the vertical direction, of the first blocking layer is substantially equal to or larger than a thickness, in the vertical direction, of the floating diffusion region.

### CROSS-REFERENCE TO RELATED APPLICATION

This application claims priority to and the benefit of Korean Patent Application No. 10-2024-0138510 filed in the Korean Intellectual Property Office on October 11, 2024, the entire contents of which are incorporated herein by reference.

### BACKGROUND

### 1. Field

The present disclosure relates to an image sensor.

### 2. Description of the Related Art

Image sensors are semiconductor devices for converting optical images into electrical signals. Image sensors may be classified into charge coupled devices (CCDs) and complementary metal oxide semiconductors (CMOSs).

As compared to CCD image sensors with high-voltage analog circuits, CMOS image sensors (CISs) have the advantages of low manufacturing costs and low power consumption due to the small sizes of elements, so the CISs are mainly mounted in home appliances including portable devices such as smart phones and digital cameras.

A pixel array included in a CMOS image sensor includes a photoelectric conversion element such as a photodiode in each pixel. The photoelectric conversion elements may generate electrical signals that vary depending on the amounts of incident light, and the CMOS image sensor may synthesize an image by processing the electrical signals.

The CMOS image sensors may include a plurality of transistors for driving a photoelectric conversion element.

Recently, in response to the demand for high-definition images, the pixels of image sensors are becoming smaller and the numbers of pixels are increasing. Accordingly, fast operation characteristics of transistors in an image sensor are desirable. As the size of the pixels decreases, multiple transistors are disposed within a small pixel area, and an operation characteristic error may occur due to unnecessary parasitic capacitance between the corresponding area and an element adjacent thereto and the influence of an adjacent area, which may cause an operation characteristic error of the image sensor.

### SUMMARY

The present disclosure attempts to provide an image sensor in which an operation characteristic error does not occur due to parasitic capacitance in the image sensor or the influence of an adjacent area.

However, objects which embodiments attempt to achieve are not limited to the above-mentioned object, and can be variously expanded without departing from the technical spirit and scope of the embodiments.

According to an aspect of the present disclosure, an image sensor includes a substrate that includes a first surface and a second surface facing each other, a plurality of photoelectric conversion elements that is positioned inside the substrate, a floating diffusion region that is adjacent to the first surface and inside the substrate, wherein the floating diffusion region is doped with an impurity, and a first blocking layer positioned in a space between the floating diffusion region and each of the plurality of photoelectric conversion elements in a vertical direction perpendicular to the first surface of the substrate. A thickness, in the vertical direction, of the first blocking layer is substantially equal to or larger than a thickness, in the vertical direction, of the floating diffusion region.

According to an aspect of the present disclosure, an image sensor includes a substrate that includes a first surface and a second surface facing each other, a plurality of photoelectric conversion elements that are positioned inside the substrate, a floating diffusion region that is adjacent to the first surface and inside the substrate, wherein the floating diffusion region is doped with an impurity, and a first blocking layer positioned in a space between the floating diffusion region and each of the plurality of photoelectric conversion elements in a vertical direction perpendicular to the first surface of the substrate. A thickness, in the vertical direction, of the first blocking layer is substantially equal to or larger than a thickness, in the vertical direction, of the floating diffusion region. The floating diffusion region includes a lower floating diffusion region in the substrate. The first blocking layer extends through the lower floating diffusion region of the floating diffusion region from the first surface of the substrate toward the second surface of the substrate so that a bottom surface of the first blocking layer is lower than a bottom surface of the lower floating diffusion region of the floating diffusion region. The lower floating diffusion region contacts a side surface of the first blocking layer.

According to embodiments, it is possible to provide an image sensor in which an operation characteristic error does not occur due to parasitic capacitance in the image sensor or the influence of an adjacent area.

However, the effects of the embodiments are not limited to the above-described effects, and it is apparent that they can be variously expanded without departing from the spirit and scope of this disclosure.

### BRIEF DESCRIPTION OF THE DRAWINGS

FIG. 1 is a block diagram schematically illustrating an image sensor according to an embodiment.

FIG. 2 is a plan view illustrating a portion of the image sensor according to the embodiment.

FIG. 3 is a circuit diagram of the image sensor according to the embodiment.

FIG. 4 is a plan view of the image sensor according to the embodiment.

FIG. 5 is a cross-sectional view taken along line I-I' of FIG. 4.

FIG. 6 is a cross-sectional view taken along line II-II' of FIG. 4.

FIGS. 7, 8, 9, and 10 are cross-sectional views illustrating a method of manufacturing the image sensor according to an embodiment.

FIG. 11 is a plan view of an image sensor according to an embodiment.

FIG. 12 is a cross-sectional view taken along line II-II' of FIG. 11.

FIGS. 13, 14, and 15 are cross-sectional views illustrating a method of manufacturing the image sensor according to an embodiment.

FIG. 16 is a plan view of an image sensor according to an embodiment.

### DETAILED DESCRIPTION

In the following detailed description, only certain embodiments of the present disclosure have been shown and described, simply by way of illustration. This disclosure can be variously implemented and is not limited to the following embodiments.

The drawings and description are to be regarded as illustrative in nature and not restrictive. Like reference numerals designate like elements throughout the specification.

Further, the accompanying drawings are provided for helping to easily understand embodiments disclosed in the present specification, and the technical spirit disclosed in the present specification is not limited by the accompanying drawings, and it will be appreciated that this disclosure includes all of the modifications, equivalent matters, and substitutes included in the spirit and the technical scope of this disclosure.

In addition, the size and thickness of each configuration shown in the drawings are arbitrarily shown for understanding and ease of description, but this disclosure is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Hereinafter, various embodiments and modifications will be described in detail with reference to the drawings.

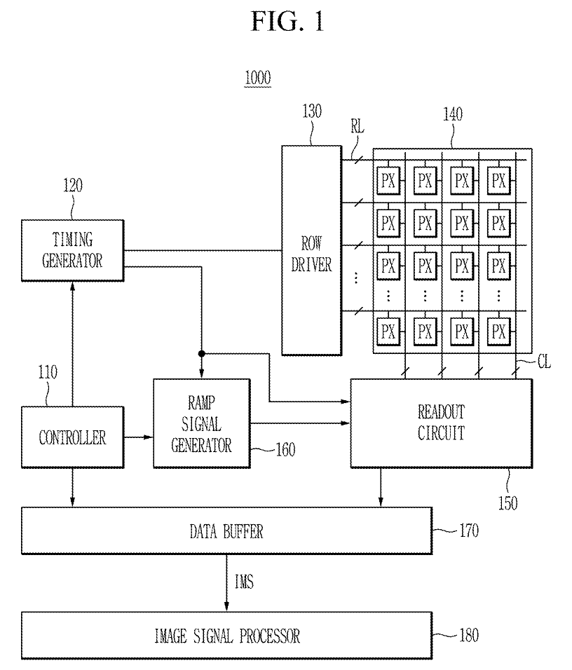

An image sensor according to an embodiment will be described in brief with reference to FIG. 1. FIG. 1 is a block diagram schematically illustrating an image sensor according to an embodiment.

Referring to FIG. 1, an image sensor 1000 according to an embodiment may include a pixel array 140 and a logic circuit that controls the pixel array 140.

The logic circuit is a circuit for controlling the pixel array 140, and may include, for example, a controller 110, a timing generator 120, a row driver 130, a readout circuit 150, a ramp signal generator 160, or a data buffer 170.

The image sensor 1000 may further include an image signal processor 180, and according to another embodiment, the image signal processor 180 may be positioned outside the image sensor 1000. The image sensor 1000 may generate an image signal by converting light received from the outside into an electrical signal. The image signal may be provided to the image signal processor 180.

The image sensor 1000 may be mounted in an electronic device having an image or light sensing function. For example, the image sensor 1000 may be mounted in electronic devices such as cameras, smart phones, wearable devices, IoT (Internet of Things) devices, home appliances, tablet PCs (personal computers), navigation devices, drones, and advanced drivers assistance systems (ADASs). The image sensor 1000 may be mounted in electronic devices which are incorporated as components in vehicles, furniture, manufacturing equipment, doors, or various measuring devices.

The pixel array 140 may include a plurality of pixels PX, and a plurality of row lines RL and a plurality of column lines CL. Each of the plurality of row lines RL and each of the plurality of column lines CL may be connected to a corresponding one of the plurality of pixels PX.

In the embodiment, each pixel PX may include at least one photoelectric conversion element. The photoelectric conversion elements may sense incident light, and convert the incident light into electrical signals according to the amounts of light, i.e., into a plurality of analog pixel signals.

Each photoelectric conversion element may be a photodiode or a pinned diode. The present disclosure is not limited thereto. In an embodiment, each photoelectric conversion element may be a single-photon avalanche diode (SPAD) which is applied to a 3D sensor pixel.

The level of an analog pixel signal which is output from a photoelectric conversion element may be proportional to the amount of charge which is output from the photoelectric conversion element. For example, the level of an analog pixel signal which is output from the photoelectric conversion element may be determined depending on the amount of light which enters the pixel array 140.

The plurality of row lines RL may be connected to the plurality of pixels PX. For example, a control signal that is output from the row driver 130 to a row line RL may be transferred to the gates of the transistors of a plurality of pixels PX connected to a corresponding row line of the plurality of row lines RL. Each column line CL may intersect the row lines RL and is connected to a plurality of pixels PX. A plurality of pixel signals which is output from the plurality of pixels PX may be transferred to the readout circuit 150 through the plurality of column lines CL.

The controller 110 may control the operation timings of the above-mentioned individual components 120, 130, 150, 160, and 170, using control signals.

In the embodiment, the controller 110 may receive a mode signal indicating an imaging mode from an application processor, and generally control the image sensor 1000 on the basis of the received mode signal. For example, the application processor may determine the imaging mode of the image sensor 1000 according to various factors such as the intensity of illumination in the imaging environment, the user's resolution setting, and a sensed or learned state, and provide the mode signal indicating the determined result to the controller 110.

The controller 110 may control the plurality of pixels PX of the pixel array 140 to output pixel signals, according to the imaging mode, and the pixel array 140 may output the pixel signals of the plurality of pixels PX or the pixel signals of some of the plurality of pixels PX, and the readout circuit 150 may sample and process the pixel signals received from the pixel array 140.

The timing generator 120 may generate a reference signal for the operation timings of the components of the image sensor 1000. The timing generator 120 may control the timings of the row driver 130, the readout circuit 150, and the lamp signal generator 160. The timing generator 120 may provide control signals to control the timings of the row driver 130, the readout circuit 150, and the lamp signal generator 160.

The row driver 130 may generate a control signal for driving the pixel array 140, in response to a control signal of the timing generator 120, and provide the control signal to a plurality of pixels PX of the pixel array 140 through the plurality of row lines RL.

In an embodiment, the row driver 130 may control the pixels PX in units of a row line, such that the pixels detect incident light. Each row line unit may include at least one row line RL. For example, the row driver 130 may generate a transmission signal for controlling transfer transistors, a reset control signal for controlling reset transistors, or a selection control signal for controlling selected transistors, and provide the signals to the pixel array 140.

The readout circuit 150 may convert the pixel signals (or electrical signals) received from pixels PX coupled to a selected row line RL among the plurality of pixels PX, into pixel values indicating light amounts, in response to a control signal from the timing generator 120.

The readout circuit 150 may convert pixel signals output through corresponding column lines CL into pixel values. For example, the readout circuit 150 may convert pixel signals into pixel values by comparing the pixel signals with lamp signals. Pixel values may be image data which have a plurality of bits. Specifically, the readout circuit 150 may include a selector, a plurality of comparators, or a plurality of counter circuits.

The lamp signal generator 160 may generate a reference signal, and transmit the reference signal to the readout circuit 150. The lamp signal generator 160 may include current sources, resistors, and capacitors. The lamp signal generator 160 may adjust lamp voltage which is voltage to be applied to a lamp resistor by adjusting the current magnitude of a variable current source or the resistance value of a variable resistor. In this way, the lamp signal generator 160 may generate a plurality of lamp signals which falls or rise at slopes determined depending on the current magnitudes of variable current sources or the resistance values of variable resistors.

The data buffer 170 may store the pixel values of a plurality of pixels PX coupled to a selected column line CL, received from the readout circuit 150, and output the stored pixel values in response to an enable signal from the controller 110.

The image signal processor 180 may perform image signal processing on image signals received from the data buffer 170. For example, the image signal processor 180 may receive a plurality of image signals from the data buffer 170, and synthesize the received image signals to generate one image.

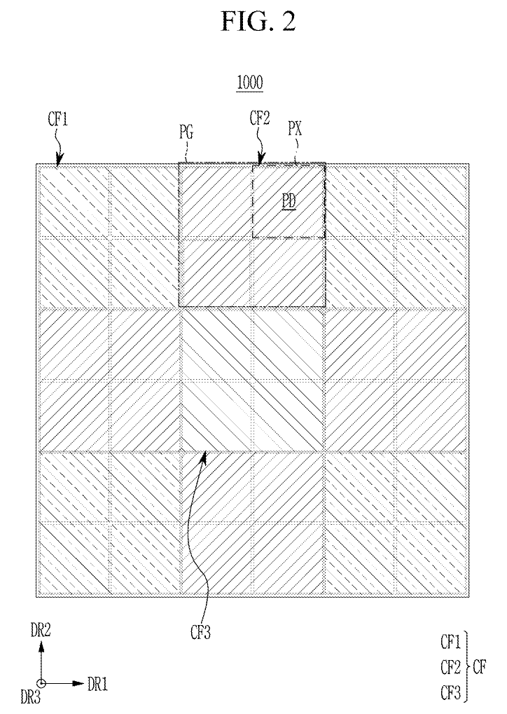

The pixel arrangement of the image sensor according to the embodiment will be described with reference to FIG. 2. FIG. 2 is a plan view illustrating a portion of the image sensor according to the embodiment.

The image sensor 1000 according to the embodiment may include pixel groups PG, photoelectric conversion elements PD, color filters CF, and other circuits necessary for the operation of the image sensor 1000.

Each of the plurality of pixels PX may include one photoelectric conversion element PD. Each photoelectric conversion element PD may include a photodiode, but the embodiment is not limited thereto.

A plurality of pixels PX may be grouped in the form of a matrix having a plurality of columns and a plurality of rows, thereby forming one unit pixel group PG.

A pixel group PG overlapping a first color filter CF1 may sense light of a first color, a pixel group PG overlapping a second color filter CF2 may sense light of a second color different from the first color, and a pixel group PG overlapping a third color filter CF3 may sense light of a third color different from the first color and the second color. According to another embodiment, the image sensor 1000 may include a pixel group for sensing all visible light.

Each of the plurality of pixel groups PG may include (NxM)-number of pixels in an NxM array. Each of N and M may independently be an integer greater than 1. For example, each of N and M may be 2 such that each pixel group may have a pixel array having a 2x2 tetra structure on a plane. For example, each of the plurality of pixel groups PG may include pixels PX arranged in a 2x2 matrix on a plane.

More specifically, a plurality of pixels PX disposed in the arrangement direction of the column lines CL and a plurality of pixels PX disposed in the arrangement direction of the row lines RL may constitute one unit pixel group PG. For example, one unit pixel group PG may include a plurality of pixels PX arranged in a matrix having two columns and two rows, and one unit pixel group PG may output one analog pixel signal. However, the embodiment is not limited thereto, and the number of pixels PX which are included in one pixel group PG may be variously changed.

The image sensor 1000 according to the embodiment may further include micro lenses, and in each of the pixel groups PG, at least one micro lens may be positioned.

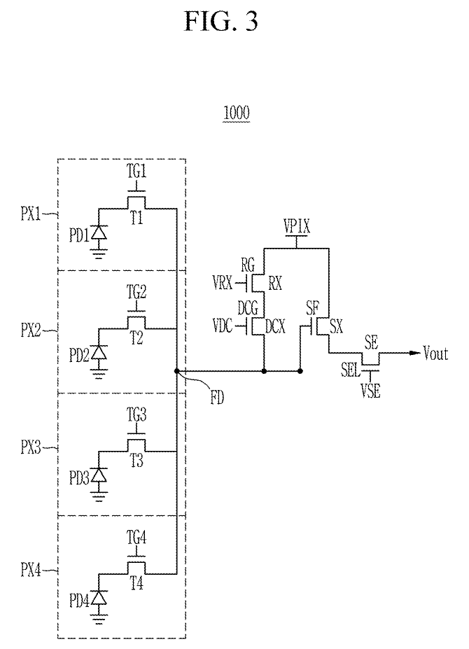

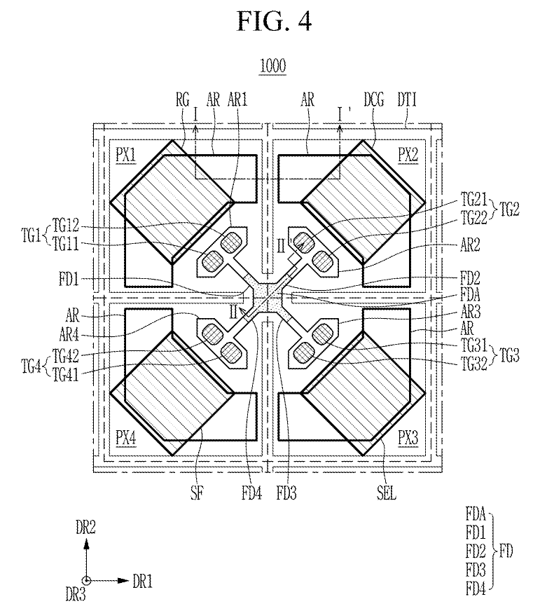

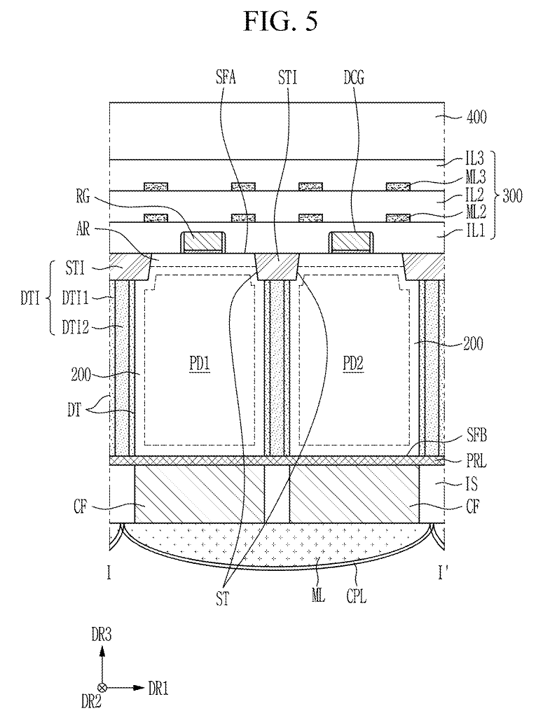

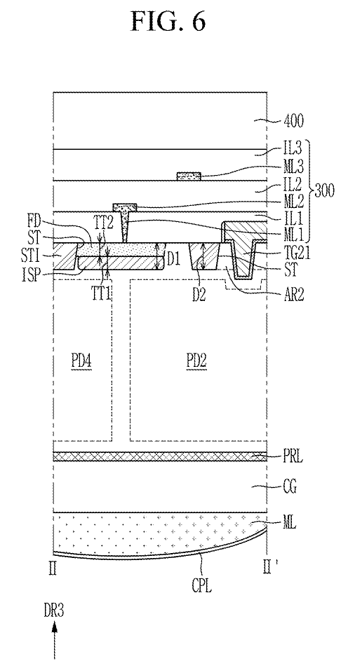

One pixel group of the image sensor according to the embodiment will be described with reference to FIGS. 3 to 6 together with FIG. 2. FIG. 3 is a circuit diagram of the image sensor according to the embodiment, FIG. 4 is a plan view of the image sensor according to the embodiment, FIG. 5 is a cross-sectional view taken along line I-I' of FIG. 4, and FIG. 6 is a cross-sectional view taken along line II-II' of FIG. 4.

Referring to FIG. 3 together with FIG. 2, a pixel group PG of the image sensor 1000 according to the embodiment may include pixels PX1, PX2, PX3, and PX4, photoelectric conversion elements PD1, PD2, PD3, and PD4, transfer transistors T1, T2, T3, and T4, a reset transistor RX, a dual conversion transistor DCX, a source follower transistor SX, and a selection transistor SE. Although it is shown in the drawing that the pixel group PG includes four pixels PX1, PX2, PX3, and PX4 including photoelectric conversion elements PD1, PD2, PD3, and PD4 as described above, the embodiment is not limited thereto.

The first pixel PX1 may include a first photoelectric conversion element PD1 and the first transfer transistor T1, the second pixel PX2 may include the second photoelectric conversion element PD2 and the second transfer transistor T2, the third pixel PX3 may include the third photoelectric conversion element PD3 and the third transfer transistor T3, and the fourth pixel PX4 may include the fourth photoelectric conversion element PD4 and the fourth transfer transistor T4.

The pixels PX1, PX2, PX3, and PX4 may share a floating diffusion region FD.

The pixels PX1, PX2, PX3, and PX4 may share the reset transistor RX, the dual conversion transistor DCX, the source follower transistor SX, and the selection transistor SE.

The floating diffusion region FD may store charge corresponding to the amount of incident light.

While the transfer transistors T1, T2, T3, and T4 are individually turned on by transmission signals, the floating diffusion region FD may receive charge from the photoelectric conversion elements PD1, PD2, PD3, and PD4 and store the charge. For example, the floating diffusion region FD may be shared by the four photoelectric conversion elements PD1, PD2, PD3, and PD4. When viewed in a plan view, the floating diffusion region FD may overlap a region defined by the four photoelectric conversion elements PD1, PD2, PD3, and PD4 which is surrounded by a photoelectric conversion element isolation pattern DTI. The floating diffusion region FD may overlap a portion of each of the four photoelectric conversion elements PD1, PD2, PD3, and PD4. The region defined by the four photoelectric conversion elements PD1, PD2, PD3, and PD4 may be disposed at a center of a region defined by an outer boundary of the photoelectric conversion element isolation pattern DTI. For example, when viewed in a plan view, the floating diffusion region FD may be disposed at the center of the region defined by an outer boundary of the photoelectric conversion element isolation pattern DTI, partially overlapping each of the four photoelectric conversion elements PD1, PD2, PD3, and PD4.

The reset transistor RX may be driven by a reset signal VRX, and may provide a power voltage to the floating diffusion region FD. As a result, the charge stored in the floating diffusion region FD may migrate to a power voltage VPIX terminal, and the voltage of the floating diffusion region FD may be reset.

The source follower transistor SX may be connected between a power voltage VPIX and the selection transistor SE. The source follower transistor SX may output an output signal Vout to the selection transistor SE on the basis of the voltage level of the floating diffusion region FD. The selection transistor SE may be driven by a selection signal VSE, and when the selection transistor SE is turned on, the output signal Vout may be output to the readout circuit 150 through a column line CL.

The dual conversion transistor DCX may be connected between the floating diffusion region FD and the reset transistor RX. When the dual conversion transistor DCX is turned off by a dual conversion signal VDC, the full well capacity (FWC) of each of the pixels PX1, PX2, PX3, and PX4 may be the capacitance of the floating diffusion region FD. When the dual conversion transistor DCX is turned on by the dual conversion signal VDC, the FWC of each of the pixels PX1, PX2, PX3, and PX4 may become higher than the capacitance of the floating diffusion region FD. Depending on whether the dual conversion transistor DCX is on or off, the conversion gain of each of the pixels PX1, PX2, PX3, and PX4 may vary.

The structure of the image sensor 1000 according to the embodiment will be described in more detail with reference to FIGS. 4 to 6 together with FIGS. 2 and 3.

Referring to FIG. 4, the image sensor 1000 according to the embodiment may include a pixel group PG including a first pixel PX1, a second pixel PX2, the third pixel PX3, and the fourth pixel PX4 disposed along a clockwise direction.

The photoelectric conversion element isolation pattern DTI may be positioned so as to surround the edges of the plurality of pixels PX1, PX2, PX3, and PX4. The photoelectric conversion element isolation pattern DTI may be positioned in at least some portions between the plurality of pixels PX1, PX2, PX3, and PX4.

The photoelectric conversion element isolation pattern DTI may prevent cross-talk between the plurality of pixels PX1, PX2, PX3, and PX4.

Referring to FIGS. 4 to 6, the image sensor 1000 may include a substrate 200. The substrate 200 may contain silicon (Si), germanium (Ge), or silicon-germanium (Si-Ge). The substrate 200 may contain gallium arsenide (GaAs), indium phosphide (InP), gallium phosphide (GaP), indium arsenide (InAs), indium antimonide (InSb), or indium gallium arsenide (InGaAs). The substrate 200 may contain zinc telluride (ZnTe) or cadmium sulfide (CdS).

The substrate 200 may be bulk silicon or a silicon-on-insulator (SOI). The substrate 200 may be a silicon substrate, or may contain other materials, for example, silicon germanium, indium antimonide, a lead tellurium compound, indium arsenide, indium phosphide, gallium arsenide, or gallium antimonide. Alternatively, the substrate 200 may be a substrate made by forming an epitaxial layer on a base substrate.

The substrate 200 may be doped with an impurity of a first conductivity type. For example, the first conductivity type may be a p-type.

The substrate 200 may have a first surface SFA and a second surface SFB opposite to each other.

The substrate 200 may include a deep trench DT, and the photoelectric conversion element isolation pattern DTI may be positioned in the deep trench DT of the substrate 200.

As described above, the photoelectric conversion element isolation pattern DTI may also be positioned at the edges of the photoelectric conversion elements PD1, PD2, PD3, and PD4 of the plurality of pixels PX1, PX2, PX3, and PX4 and in at least some portions between the photoelectric conversion elements PD1, PD2, PD3, and PD4 of the plurality of pixels PX1, PX2, PX3, and PX4. For example, the photoelectric conversion element isolation pattern DTI may include a closed-loop portion and four branch portions extending from the closed-loop portion toward a center of the closed-loop portion. Each branch portion may extend along a straight line passing through the center of the closed-loop portion. One end of a branch portion is connected to the closed-loop portion, and the other end of the branch is not connected to another branch portion. When viewed in a plan view, each branch portion may be disposed in a space between two adjacent pixels. In an embodiment, the closed-loop portion may have a shape such as a square and rectangular.

The deep trench DT and the photoelectric conversion element isolation pattern DTI may pass through the substrate 200 from the first surface SFA to second surface SFB of the substrate 200.

The photoelectric conversion element isolation pattern DTI may include a first pattern DTI1, a second pattern DTI2, and a shallow trench isolation pattern STI positioned inside a shallow trench ST. The first pattern DTI1 may cover the inner wall of the deep trench DT. The second pattern DTI2 may fill the lower portion of the deep trench DT. The shallow trench isolation pattern STI may be disposed on the first pattern DTI1 and the second pattern DTI2. In some embodiment, the first pattern DTI1 may be indistinguishable from the second pattern DTI2.

The second pattern DTI2 may be isolated from the substrate 200 by the first pattern DTI1and the shallow trench isolation pattern STI.

The first pattern DTI1 and the shallow trench isolation pattern STI may contain silicon oxide, silicon nitride, or silicon oxynitride. The first pattern DTI1 may contain a metal oxide such as hafnium oxide, aluminum oxide, or tantalum oxide, and in this case, the first pattern DTI1 may act as a negative fixed charge layer. The second pattern DTI2 may contain a semiconductor material such as polysilicon doped with an n-type impurity or a p-type impurity.

The photoelectric conversion elements PD1, PD2, PD3, and PD4 corresponding to the individual pixels PX1, PX2, PX3, and PX4 may be positioned inside the substrate 200.

Externally incident light may be converted into electrical signals in the photoelectric conversion elements PD1, PD2, PD3, and PD4. The photoelectric conversion elements PD1, PD2, PD3, and PD4 may include photodiodes inside the substrate 200. The photoelectric conversion elements PD1, PD2, PD3, and PD4 may be doped with a conductive impurity different from a conductive impurity doped into the substrate 200.

The photoelectric conversion elements PD1, PD2, PD3, and PD4 may be doped with an impurity of a second conductivity type different from the impurity of the first conductivity type doped into the substrate 200. For example, the substrate 200 may be doped with a p-type impurity, and the photoelectric conversion elements PD1, PD2, PD3, and PD4 may be doped with an n-type impurity.

The n-type impurity regions of the photoelectric conversion elements PD1, PD2, PD3, and PD4 may form p-n junctions with the p-type impurity region of the substrate 200 around them, thereby constituting photodiodes, and when light enters there, electron-hole pairs may be generated by the p-n junctions (e.g., at a depletion region at the boundary between the substrate and each of the photoelectric conversion elements PD1, PD2, PD3, and PD4).

In at least some portions between the photoelectric conversion elements PD1, PD2, PD3, and PD4 corresponding to the plurality of pixels PX1, PX2, PX3, and PX4, the photoelectric conversion element isolation pattern DTI may be positioned such that the photoelectric conversion elements PD1, PD2, PD3, and PD4, corresponding to the plurality of pixels PX1, PX2, PX3, and PX4, respectively, are isolated from each other in at least some portions by the photoelectric conversion element isolation pattern DTI. The photoelectric conversion element isolation pattern DTI may electrically and optically isolate the photoelectric conversion elements PD1, PD2, PD3, and PD4 adjacent to one another.

The substrate 200 may include the shallow trench ST, and the shallow trench isolation pattern STI may be positioned inside the shallow trench ST of the substrate 200. The shallow trench ST may be formed at the first surface FSA of the substrate 200. For example, the shallow trench ST may be positioned in a portion of the substrate 200, without passing through the substrate 200 from the first surface SFA of the substrate 200. In a third direction DR3 which is a height direction (i.e., a vertical direction perpendicular to the first surface SFA of the substrate), the depth of the shallow trench ST may be smaller than the depth of the deep trench DT. The shallow trench isolation pattern STI may contain silicon oxide, silicon nitride, or a combination thereof.

Alternatively, the shallow trench isolation pattern STI may be a region doped with an impurity of the same first conductivity type as that of the impurity implanted into the substrate 200 at a concentration higher than the doping concentration of the impurity doped into the substrate 200.

The photoelectric conversion element isolation pattern DTI may pass through the shallow trench isolation pattern STI. In some embodiments, the first pattern DTI1 may be connected to the shallow trench isolation pattern STI, and the shallow trench isolation pattern STI and the first pattern DTI1 may be indistinguishable from each other.

On the first surface SFA of the substrate 200, a plurality of gate electrodes TG1, TG2, TG3, TG4, RG, DCG, SF, and SEL may be positioned.

The plurality of pixels PX1, PX2, PX3, and PX4 may include active regions AR1, AR2, AR3, and AR4 positioned installed in the substrate 200 so as to adjacent to the first surface SFA of the substrate 200, respectively. The active regions AR1, AR2, AR3, and AR4 may be isolated by the shallow trench isolation pattern STI. The active regions AR1, AR2, AR3, and AR4 may be collectively referred to as AR.

The substrate 200 may include the floating diffusion region FD and ground regions (not shown in the drawings) positioned adjacent to the first surface SFA.

The floating diffusion region FD may be adjacent to transfer gate electrodes TG1, TG2, TG3, and TG4, and the floating diffusion region FD may be doped with an impurity of the second conductivity type different from the impurity of the first conductivity type doped into the substrate 200.

The ground regions may be doped with the same conductive impurity as the conductive impurity doped into the substrate 200, and the concentration of the implemented conductive impurity may be higher than the concentration of other region of the substrate 200.

The active regions AR of the plurality of pixels PX1, PX2, PX3, and PX4 may be active regions for the operation of the plurality of transistors.

The plurality of gate electrodes TG1, TG2, TG3, TG4, RG, DCG, SF, and SEL may be positioned on the active regions AR1, AR2, AR3, and AR4 of the plurality of pixels PX1, PX2, PX3, and PX4.

The plurality of gate electrodes TG1, TG2, TG3, TG4, RG, DCG, SF, and SEL may form the transfer transistors T1, T2, T3, and T4, the reset transistor RX, the dual conversion transistor DCX, the source follower transistor SX, and the selection transistor SE, respectively. The ground regions may be a ground pattern for grounding at least one of the transfer transistors T1, T2, T3, and T4, the selection transistor SE, the reset transistor RX, and the dual conversion transistor DCX.

On the first surface SFA of the substrate 200, a first structure 300 may be disposed. The first structure 300 may include a plurality of vias ML1, a plurality of wiring layers ML2 and ML3, and a plurality of insulating layers IL1, IL2, and IL3. The plurality of insulating layers IL1, IL2, and IL3 may electrically isolate the plurality of vias ML1 and the plurality of wiring layers ML2 and ML3.

The plurality of vias ML1 and the plurality of wiring layers ML2 and ML3 may be electrically connected to the transistors on the first surface SFA of the substrate 200.

The plurality of vias ML1 and the plurality of wiring layers ML2 and ML3 may contain tungsten, aluminum, copper, tungsten silicide, titanium silicide, tungsten nitride, titanium nitride, or doped polysilicon.

The plurality of insulating layers IL1, IL2, and IL3 may contain an insulating material such as silicon oxide, silicon nitride, silicon oxynitride, and a low-dielectric constant (low-k) material. The low-dielectric constant material may contain at least one of, for example, flowable oxide (FOX), torene silazene (TOSZ), undoped silica glass (USG), borosilica glass (BSG), phosphosilica glass (PSG), borophosphosilica glass (BPSG), plasma enhanced tetra-ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric materials, and a combination thereof.

The image sensor 1000 may further include a support substrate 400 which is positioned on the first structure 300, but the support substrate 400 may be omitted. Between the support substrate 400 and the first structure 300, an adhesive member (not shown in the drawings) may be further positioned.

On the second surface SFB of the substrate 200, an antireflective layer PRL may be positioned. The antireflective layer PRL may cover the second surface SFB of the substrate 200 and the photoelectric conversion element isolation pattern DTI.

The antireflective layer PRL may contain hafnium oxide (HfO2), silicon oxide (SiO2), silicon nitride (SiN), aluminum oxide (Al2O3), zirconium oxide (ZrO2), tantalum oxide (Ta2O5), titanium oxide (TiO2), lanthanum oxide (La2O3), praseodymium oxide (Pr2O3), cerium oxide (CeO2), neodymium oxide (Nd2O3), promethium oxide (Pm2O3), samarium oxide (Sm2O3), europium oxide (Eu2O3), gadolinium oxide (Gd2O3), terbium oxide (Tb2O3), dysprosium oxide (Dy2O3), holmium oxide (Ho2O3), thulium oxide (Tm2O3), ytterbium oxide (Yb2O3), lutetium oxide (Lu2O3), yttrium oxide (Y2O3), or a combination thereof.

In an embodiment, the antireflective layer PRL may include a plurality of layers containing different materials and having different thicknesses. For example, the antireflective layer PRL may include a first antireflective layer to a third antireflective layer sequentially stacked on the second surface SFB of the substrate 200.

The first antireflective layer may be a fixed charge layer having negative fixed charge. Hole accumulation of holes may occur around the fixed charge layer, whereby it is possible to effectively reduce occurrence of dark current and white spots.

The third antireflective layer may contain a metal oxide or a metal fluoride containing at least one of hafnium (Hf), zirconium (Zr), aluminum (Al), tantalum (Ta), titanium (Ti), and yttrium (Y). For example, the first antireflective layer and the third antireflective layer may include a hafnium oxide layer, and the second antireflective layer may contain silicon oxide and/or silicon nitride. However, in other embodiments, the number and relative thicknesses of layers constituting the antireflective layer PRL may be variously changed.

In other embodiments, the antireflective layer PRL may further include a silicon nitride layer which is disposed between the second antireflective layer and the third antireflective layer.

Fence patterns IS may surround the color filters CF.

The fence patterns IS may contain a low-refractive-index material. The low-refractive-index material may have a refractive index larger than about 1.0 and equal to or smaller than about 1.4. For example, the low-refractive-index material may contain polymethylmetacrylate (PMMA), silicon acrylate, cellulose acetatebutyrate (CAB), silica, or fluoro-silicon acrylate (FSA). For example, the low-refractive-index material may contain a polymer material including silica (SiOx) particles dispersed therein. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

When the fence patterns IS contain a low-refractive-index material having a relatively low refractive index, incident light toward the fence patterns IS may be totally reflected, thereby being directed toward the center portion of each of the pixels PX1, PX2, PX3, and PX4.

The fence patterns IS may prevent light obliquely incident into a color filter CF located in one of the plurality pixels PX1, PX2, PX3, and PX4 from entering another color filter CF located in another one of the plurality pixels PX1, PX2, PX3, and PX4, thereby preventing cross-talk between the plurality of pixels PX1, PX2, PX3, and PX4.

The plurality of color filters CF may be disposed on the antireflective layer PRL, and isolated from one another by the fence pattern IS. The plurality of color filters CF may include, for example, a green filter, a blue filter, and a red filter. The plurality of color filters CF may include, for example, a cyan filter, a magenta filter, or a yellow filter.

A micro lens ML may be disposed on the color filter CF and the fence pattern IS.

The micro lens ML may be transparent. The micro lens ML may be formed on a resin-based material such as styrene-based resin, an acrylic resin, a styrene-acrylic copolymer resin, and a siloxane-based resin.

The micro lens ML may concentrate incident light, and the concentrated light may enter the photoelectric conversion elements PD1, PD2, PD3, and PD4 through the color filter CF.

A capping layer CPL may be disposed on the micro lens ML to protect the micro lens ML.

As shown in FIG. 4, the first transfer gate electrode TG1 which is positioned in the first pixel PX1 may include two transfer gate electrodes TG11 and TG12, and the two transfer gate electrodes TG11 and TG12 may overlap the first active region AR1. The second transfer gate electrode TG2 which is positioned in the second pixel PX2 may include two transfer gate electrodes TG21 and TG22, and the two transfer gate electrodes TG21 and TG22 may overlap the second active region AR2. The third transfer gate electrode TG3 which is positioned in the third pixel PX3 may include two transfer gate electrodes TG31 and TG32, and the two transfer gate electrodes TG31 and TG32 may overlap the third active region AR3. The fourth transfer gate electrode TG4 which is positioned in the fourth pixel PX4 may include two transfer gate electrodes TG41 and TG42, and the two transfer gate electrodes TG41 and TG42 may overlap the fourth active region AR4.

The floating diffusion region FD may include a center floating diffusion region FDA that is positioned at the center of the closed-loop portion of the photoelectric conversion element isolation pattern DTI enclosing the first pixel PX1, the second pixel PX2, the third pixel PX3, and the fourth pixel PX4. The floating diffusion region FDA may further include a first extended floating diffusion region FD1 that is positioned in the first pixel PX1 and connected to the first active region AR1, a second extended floating diffusion region FD2 that is positioned in the second pixel PX2 and connected to the second active region AR2, a third extended floating diffusion region FD3 that is positioned in the third pixel PX3 and connected to the third active region AR3, and a fourth extended floating diffusion region FD4 that is positioned in the fourth pixel PX4 and connected to the fourth active region AR4. The extended floating diffusion region FD1 of the first pixel PX1, the extended floating diffusion region FD2 of the second pixel PX2, the extended floating diffusion region FD3 of the third pixel PX3, and the extended floating diffusion region FD4 of the fourth pixel PX4 may be connected to the center floating diffusion region FDA. The first to fourth extended floating diffusion regions FD1 to FD4, and the center floating diffusion region FDA may be integrally formed.

The center floating diffusion region FDA of the floating diffusion region FD may be positioned at the center of the closed-loop portion of the photoelectric conversion element isolation pattern DTI enclosing the first pixel PX1, the second pixel PX2, the third pixel PX3, and the fourth pixel PX4, and the photoelectric conversion element isolation pattern DTI may not be positioned at the position corresponding to the floating diffusion region FD.

Referring to FIG. 6, the image sensor 1000 according to the embodiment may include a blocking layer ISP which is positioned below the floating diffusion region FD in the height direction DR3. The blocking layer ISP may be positioned between the floating diffusion region FD and the photoelectric conversion elements PD1, PD2, PD3, and PD4. For example, the blocking layer ISP may be positioned at a depletion region of a p-n junction formed at a boundary between the floating diffusion region FD and the substrate 200, thereby reducing an area of the depletion region (i.e., reducing a depletion capacitance of the floating diffusion region FD). The depletion region may be part of the floating diffusion region FD. The blocking layer ISP may not extend into a depletion region of a p-n junction formed at a boundary between the substrate 200 and each of the photoelectric conversion elements PD1, PD2, PD3, and PD4, thereby not reducing an area of the photoelectric conversion elements PD1, PD2, PD3, and PD4 where electron-hole pairs are generated by an incident light.

The blocking layer ISP may be an insulating layer. The blocking layer ISP may contain an oxide such as silicon oxide. However, the embodiment is not limited thereto.

The maximum depth D1 of the blocking layer ISP measured from the first surface SFA of the substrate 200 may be substantially equal to or smaller than the depth D2 of the shallow trench ST defining the shallow trench isolation pattern STI.

A first thickness TT1 of the blocking layer ISP may be substantially equal to or larger than a second thickness TT2 of the floating diffusion region FD. For example, the second thickness TT2 of the floating diffusion region FD may be about 100 nm to about 150 nm, and the first thickness TT1 of the blocking layer ISP may be about 100 nm to about 150 nm, or greater; however, the embodiment is not limited thereto.

The blocking layer ISP may be positioned between the substrate 200 doped with the impurity of the first conductivity type and the floating diffusion region FD doped with the impurity of the second conductivity type different from the impurity of the first conductivity type. Accordingly, the blocking layer ISP may reduce p-n junction capacitance (i.e., depletion capacitance of the p-n junction) which may occur at a boundary between the substrate 200 and the floating diffusion region FD doped with the impurities of the different conductivity types.

PN junction capacitance may generated between the substrate 200 and the floating diffusion region FD doped with the impurities of the different conductivity types, and a portion of the charge accumulated in the floating diffusion region FD may be trapped in the p-n junction capacitance, so the output of the image sensor 1000 may be changed. Under low illumination conditions, the amount of charge accumulated in the floating diffusion (FD) region is relatively small, making the influence of noise due to the PN junction capacitance more significant.

However, the image sensor 1000 according to the embodiment may include the blocking layer ISP which is positioned between the substrate 200 doped with the impurity of the first conductivity type and the floating diffusion region FD doped with the impurity of the second conductivity type, thereby reducing the PN junction area between the substrate 200 and the floating diffusion region FD, so it is possible to reduce PN junction capacitance between the substrate 200 and the floating diffusion region FD. Therefore, it is possible to reduce occurrence of noise according to a change in the output of the image sensor 1000, particularly, occurrence of noise at low illumination.

As described above, the first thickness TT1 of the blocking layer ISP may be substantially equal to or larger than the second thickness TT2 of the floating diffusion region FD. In case that the first thickness TT1 of the blocking layer ISP is smaller than the second thickness TT2 of the floating diffusion region FD, it may be difficult to reduce the p-n junction capacitance by the blocking layer ISP. However, according to the embodiment, since the first thickness TT1 of the blocking layer ISP is substantially equal to or larger than the second thickness TT2 of the floating diffusion region FD, it is possible to prevent occurrence of the p-n junction capacitance by the blocking layer ISP.

As described above, the maximum depth D1 of the blocking layer ISP measured from the first surface SFA of the substrate 200 may be substantially equal to or smaller than the depth D2 of the shallow trench ST defining the shallow trench isolation pattern STI. Accordingly, an influence which the blocking layer ISP may have on the photoelectric conversion elements PD1, PD2, PD3, and PD4 due to the addition of the blocking layer ISP, such as occurrence of dark current, may be prevented. A reduction in the area of the photoelectric conversion elements PD1, PD2, PD3, and PD4 within the substrate 200 by the addition of the blocking layer ISP within the substrate 200 may be reduced.

According to the embodiment, by adjusting the first thickness TT1 and maximum depth D1 of the blocking layer ISP, it is possible to prevent an influence which the blocking layer ISP may have on the photoelectric conversion elements PD1, PD2, PD3, and PD4 and avoid a decrease in the area of the photoelectric conversion elements PD1, PD2, PD3, and PD4 while preventing occurrence of p-n junction capacitance by the blocking layer ISP. For example, when the blocking layer ISP extends into the photoelectric conversion elements PD1, PD2, PD3, and PD4, an areas thereof where electron-hole pairs are generated by an incident light are reduced.

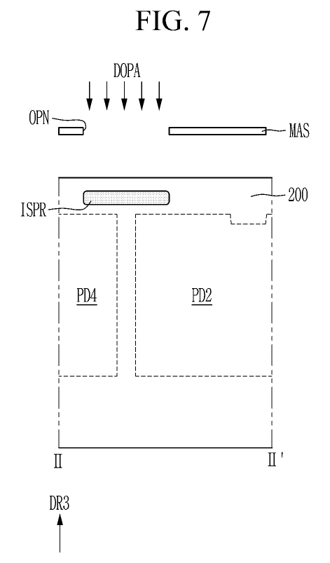

A method of manufacturing the image sensor according to an embodiment will be described with reference to FIGS. 7 to 10 together with FIGS. 1 to 6. FIGS. 7 to 10 are cross-sectional views illustrating a method of manufacturing the image sensor according to an embodiment. FIGS. 7 to 10 are cross-sectional views taken along line II-II' of FIG. 4.

Referring to FIG. 7 together with FIGS. 1 to 6, an ion implantation process DOPA may be performed using a mask MAS having an opening OPN corresponding to the floating diffusion region FD, such that a preliminary blocking region ISPR having desired ions implanted therein is formed inside the substrate 200. For example, the ion implantation process DOPA may implant oxygen (O2), but the embodiment is not limited thereto. In this case, by adjusting the implantation angle or implantation amount of the ion implantation process DOPA, it is possible to form a preliminary blocking region ISPR in a region having a predetermined thickness and depth.

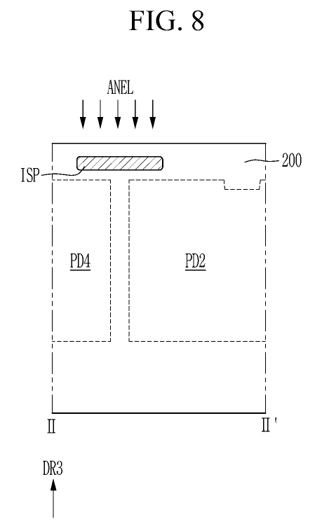

Referring to FIG. 8, an annealing process ANEL may be performed on the preliminary blocking region ISPR to cause a reaction of the ions implanted into the preliminary blocking region ISPR, such that the blocking layer ISP is formed. For example, a reaction between the oxygen implanted into the preliminary blocking region ISPR and the silicon of the substrate 200 may be caused to form the blocking layer ISP containing silicon oxide, but the embodiment is not limited thereto. The annealing process ANEL may be performed at a temperature of about 1300°C, but the embodiment is not limited thereto.

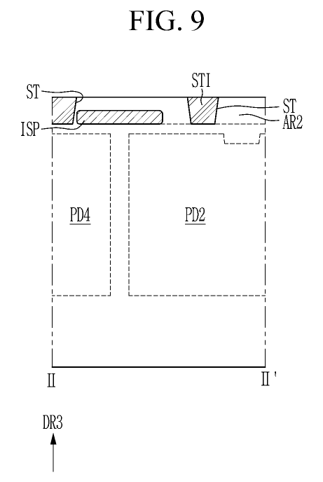

Referring to FIG. 9, the shallow trench ST and the shallow trench isolation pattern STI which is positioned inside the shallow trench ST may be formed in the substrate 200, thereby defining the active regions AR1, AR2, AR3, and AR4. Subsequently, the photoelectric conversion element isolation pattern DTI and the gate electrodes TG1, TG2, TG3, TG4, RG, DCG, SF, and SEL also may be formed.

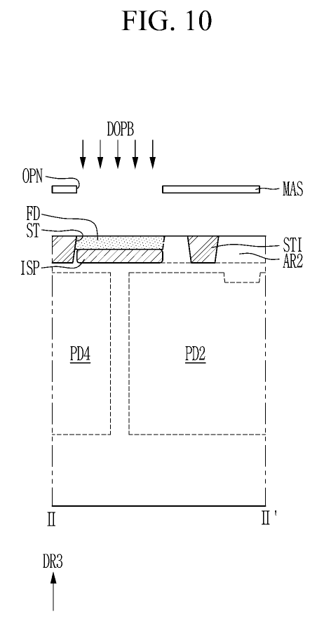

Referring to FIG. 10, a doping process DOPB for implanting the impurity of the second conductivity type may be performed using a mask MAS having an opening OPN corresponding to the floating diffusion region FD, such that the floating diffusion region FD doped with the impurity of the second conductivity type is formed. In an embodiment, the mask MAS of FIG. 10 may be the same as the mask MAS of FIG. 7.

As described above, when the blocking layer ISP is formed, the annealing process ANEL may be performed. Since the annealing process ANEL requires a high temperature, in order to prevent a structure from being damaged during the high-temperature process, after the blocking layer ISP is formed, other structures such as the shallow trench ST may be formed inside the substrate 200.

According to the method of manufacturing the image sensor according to the embodiment, by forming the floating diffusion region by the impurity implantation process after forming the blocking layer ISP through the ion implantation process and the annealing process, it is possible to manufacture the image sensor including the blocking layer ISP without complicating or affecting the other manufacturing processes which are not compatible with the high temperature of the annealing process.

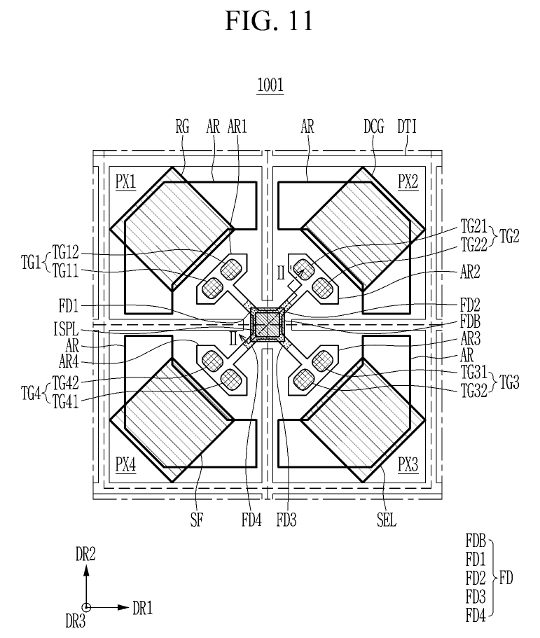

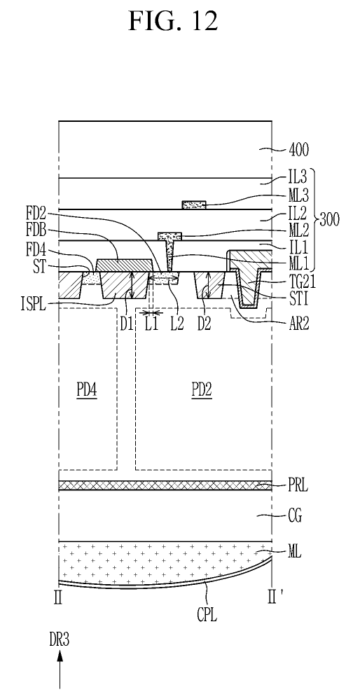

An image sensor 1001 according to an embodiment will be described with reference to FIGS. 11 and 12. FIG. 11 is a plan view of an image sensor according to an embodiment, and FIG. 12 is a cross-sectional view taken along line II-II' of FIG. 11.

Referring to FIGS. 11 and 12, the image sensor 1001 according to the present embodiment is similar to the image sensor 1000 according to the embodiment described above. A detailed description of identical constituent elements will not be made.

Referring to FIGS. 11 and 12, the image sensor 1001 according to the present embodiment may include a blocking layer ISPL which is positioned at the center of the closed-loop portion of the photoelectric conversion element isolation pattern DTI enclosing the first pixel PX1, the second pixel PX2, the third pixel PX3, and the fourth pixel PX4.

The floating diffusion region FD may include a first extended floating diffusion region FD1 that is connected to the first active region AR1 of the first pixel PX1, a second extended floating diffusion region FD2 that is positioned in the second pixel PX2 and connected to the second active region AR2 of the second pixel PX2, a third extended floating diffusion region FD3 that is positioned in the third pixel PX3 and connected to the third active region AR3 of the third pixel PX3, a fourth extended floating diffusion region FD4 that is positioned in the fourth pixel PX4 and connected to the fourth active region AR4 of the fourth pixel PX4, and an upper floating diffusion region FDB that is connected to the first to fourth extended floating diffusion regions FD1, FD2, FD3, and FD4 (i.e., lower floating diffusion regions).

The first extended floating diffusion region FD1, the second extended floating diffusion region FD2, the third extended floating diffusion region FD3, and the fourth extended floating diffusion region FD4 may be positioned on the side surface of the blocking layer ISPL, and the upper floating diffusion region FDB may be positioned on the blocking layer ISPL. For example, the upper floating diffusion region FDB may be disposed on a top surface of the blocking layer ISPL.

Side surfaces of the blocking layer ISPL may contact the first extended floating diffusion region FD1, the second extended floating diffusion region FD2, the third extended floating diffusion region FD3, and the fourth extended floating diffusion region FD4. The term “contact,” as used herein, refers to a direct connection (i.e., physical touching) unless the context indicates otherwise.

The blocking layer ISPL may extend from the first surface SFA of the substrate 200 into the substrate 200, and the maximum depth D1 of the blocking layer ISPL measured from the first surface SFA of the substrate 200 may be substantially equal to or smaller than the depth D2 of the shallow trench ST defining the shallow trench isolation pattern STI.

The upper floating diffusion region FDB may overlap or contact the first extended floating diffusion region FD1, the second extended floating diffusion region FD2, the third extended floating diffusion region FD3, and the fourth extended floating diffusion region FD4 in the height direction DR3. Accordingly, the upper floating diffusion region FDB and the first to fourth extended floating diffusion regions FD1, FD2, FD3, and FD4 may be connected to each other.

In the height direction DR3, the blocking layer ISPL may be positioned between the upper floating diffusion region FDB and the photoelectric conversion elements PD1, PD2, PD3, and PD4.

In a plane direction perpendicular (i.e., a horizontal direction parallel to the first surface FSA of the substrate 200) to the height direction DR3, the width L1 of the overlapping portion between the upper floating diffusion region FDB and the first to fourth extended floating diffusion regions FD1, FD2, FD3, and FD4 may be smaller than the width L2 of the first to fourth extended floating diffusion regions FD1, FD2, FD3, and FD4.

The upper floating diffusion region FDB may contain crystalline silicon doped with an impurity, and the impurity implanted into the upper floating diffusion region FDB may be the same conductivity type as that of the impurity implanted into the first to fourth extended floating diffusion regions FD1, FD2, FD3, and FD4 and may have substantially the same doping concentration as that of the first to fourth extended floating diffusion regions.

The image sensor 1001 according to the embodiment may include the blocking layer ISPL that is positioned inside the substrate 200 doped with the impurity of the first conductivity type, and the upper floating diffusion region FDB that is doped with the impurity of the second conductivity type and positioned on the blocking layer ISPL, such that the upper floating diffusion region FDB and the substrate 200 may not contact each other. Accordingly, it is possible to reduce the PN junction area between the substrate 200 and the floating diffusion region FD, thereby reducing p-n junction capacitance at a boundary between the substrate 200 and the floating diffusion region FD doped with the impurities of the different conductivity types. Therefore, it is possible to reduce occurrence of noise according to a change in the output of the image sensor 1001, particularly, occurrence of noise at low illumination.

As described above, the maximum depth D1 of the blocking layer ISPL measured from the first surface SFA of the substrate 200 may be substantially equal to or smaller than the depth D2 of the shallow trench ST defining the shallow trench isolation pattern STI. Accordingly, an influence which the blocking layer ISPL may have on the photoelectric conversion elements PD1, PD2, PD3, and PD4 due to the addition of the blocking layer ISP, such as occurrence of dark current, may be prevented. A reduction in the area of the photoelectric conversion elements PD1, PD2, PD3, and PD4 within the substrate 200 by the addition of the blocking layer ISPL within the substrate 200 may be reduced.

As described above, in a plane direction perpendicular to the height direction DR3, the width L1 of the overlapping portion between the upper floating diffusion region FDB and the first to fourth extended floating diffusion regions FD1, FD2, FD3, and FD4 may be smaller than the width L2 of the first to fourth extended floating diffusion regions FD1, FD2, FD3, and FD4, and accordingly, since the region which is occupied by the upper floating diffusion region FDB does not extend to the region which is occupied by the first to fourth extended floating diffusion regions FD1, FD2, FD3, and FD4, the upper floating diffusion region FDB and the substrate 200 may not contact each other, and thus, an unnecessary junction region may not be added.

All of many features of the image sensor 1000 according to the embodiment described above are applied to the image sensor 1001 according to the present embodiment.

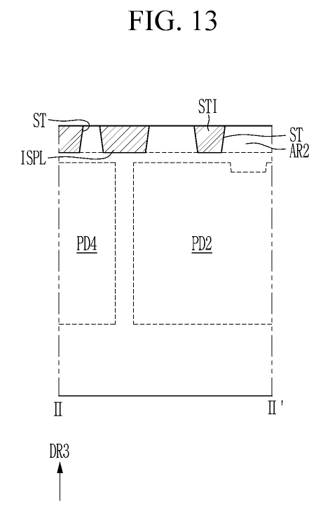

A method of manufacturing the image sensor according to an embodiment will be described with reference to FIGS. 13 to 15 together with FIGS. 11 and 12. FIGS. 13 to 15 are cross-sectional views illustrating a method of manufacturing the image sensor according to an embodiment. FIGS. 13 to 15 are cross-sectional views taken along line II-II' of FIG. 11.

Referring to FIG. 13, the shallow trench ST defining the active regions AR1, AR2, AR3, and AR4 are formed and the shallow trench isolation pattern STI may be formed in the shallow trench ST, and the blocking layer ISPL may be formed in the center portion of the region occupied by the first pixel PX1, the second pixel PX2, the third pixel PX3, and the fourth pixel PX4. The blocking layer ISPL may be an insulating layer. The blocking layer ISPL may contain an oxide such as silicon oxide. However, the embodiment is not limited thereto. Subsequently, the photoelectric conversion element isolation pattern DTI and the gate electrodes TG1, TG2, TG3, TG4, RG, DCG, SF, and SEL also may be formed.

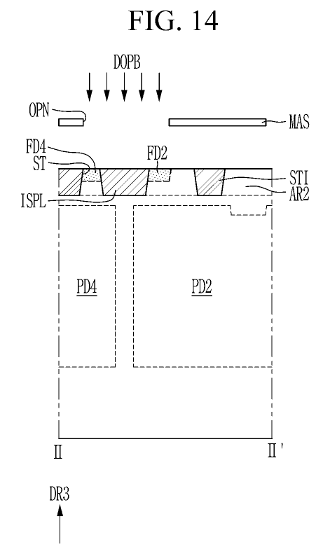

Referring to FIG. 14, a doping process DOPB for implanting the impurity of the second conductivity type may be performed using a mask MAS having an opening OPN corresponding to the floating diffusion region FD, such that the first to fourth extended floating diffusion regions FD1, FD2, FD3, and FD4 doped with the impurity of the second conductivity type are formed. In this case, the blocking layer ISPL may serve as an additional mask such that the impurity is not implanted into the region where the blocking layer ISPL is positioned.

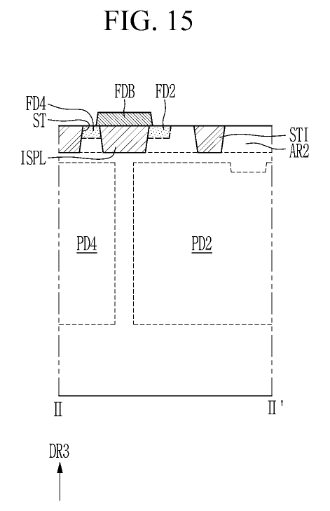

Referring to FIG. 15, the upper floating diffusion region FDB may be formed on the blocking layer ISPL such that the upper floating diffusion region FDB overlaps the first to fourth extended floating diffusion regions FD1, FD2, FD3, and FD4 in the height direction DR3. For example, a crystalline silicon layer may be stacked and patterned, and then doped with an impurity, such that the upper floating diffusion region FDB is formed, but the embodiment is not limited thereto.

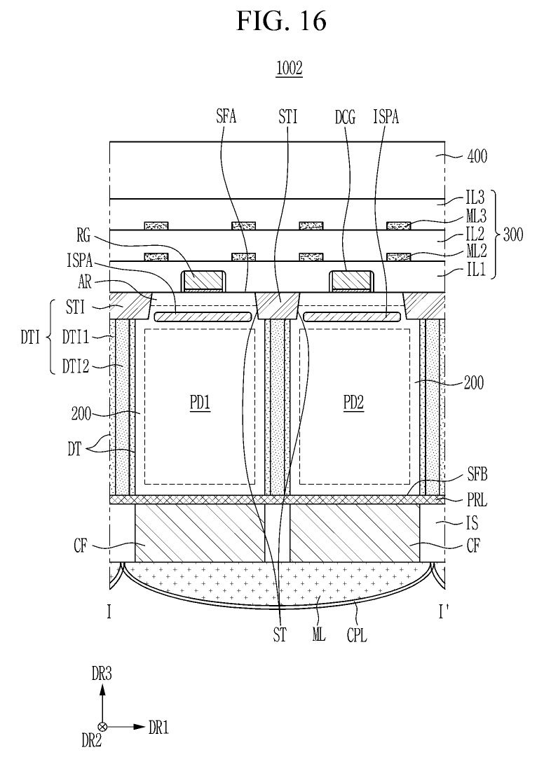

An image sensor according to an embodiment will be described with reference to FIG. 16. FIG. 16 is a cross-sectional view taken along line I-I' of FIG. 4.

A floating diffusion region FD of an image sensor 1002 according to the present embodiment may be identical to the floating diffusion region FD of the image sensor 1000 or 1001 according to the embodiments described above. This will not be described in detail.

Referring to FIG. 16, the image sensor 1002 according to the present embodiment may include additional blocking layers ISPA that are positioned below the active regions AR of the plurality of pixels PX1, PX2, PX3, and PX4 and overlap the gate electrodes TG1, TG2, TG3, TG4, RG, DCG, SF, and SEL.

The additional blocking layers ISPA may be insulating layers, similar to the blocking layer ISP or ISPL. The additional blocking layers ISPA may contain an oxide such as silicon oxide; however, the embodiment is not limited thereto.

Similar to the blocking layers ISP and ISPL, the maximum depth of each of the additional blocking layers ISPA measured from the first surface SFA of the substrate 200 may be substantially equal to or smaller than the depth D2 of the shallow trench ST defining the shallow trench isolation pattern STI.

The additional blocking layers ISPA may electrically insulate the photoelectric conversion elements PD1, PD2, PD3, and PD4 and the active regions AR, thereby preventing unnecessary mutual effects between micro elements that may occur as the size of the image sensor decreases.

All of many features of the image sensors 1000 and 1001 according to the embodiments described above are applied to the image sensor 1002 according to the present embodiment.

While this disclosure has been described in connection with what is presently considered to be practical embodiments, it is to be understood that this disclosure is not limited to the disclosed embodiments. On the contrary, it is intended to cover various modifications and equivalent arrangements included within the spirit and scope of the appended claims.

### <Description of symbols>

1000, 1001, 1002: Image Sensor

PX, PX1, PX2, PX3, PX4: Pixel

PG: Pixel Group

CF, CF1, CF2, CF3: Color Filter

PD, PD1, PD2, PD3, PD4: Photoelectric Conversion Element

FD, FDA, FDB, FD1, FD2, FD3, FD4: Floating Diffusion Region

AR, AR1, AR2, AR3, AR4: Active Region

DTI: Photoelectric Conversion Element Isolation Pattern

TG1, TG2, TG3, TG:4 Transfer Gate Electrode

RG, DCG, SF, SEL: Gate Electrode

T1, T2, T3, T4: Transfer Transistor

RX: Reset Transistor

SX: Source Follower Transistor

SE : Selection Transistor

DCX: Dual Conversion Transistor

ISP, IPSL, ISPA: Blocking Layer

What is claimed is:

1. An image sensor comprising:
a substrate that includes a first surface and a second surface facing each other;
a plurality of photoelectric conversion elements that is positioned inside the substrate;
a floating diffusion region that is adjacent to the first surface and inside the substrate, wherein the floating diffusion region is doped with an impurity; and
a first blocking layer positioned in a space between the floating diffusion region and each of the plurality of photoelectric conversion elements in a vertical direction perpendicular to the first surface of the substrate,
wherein a thickness, in the vertical direction, of the first blocking layer is substantially equal to or larger than a thickness, in the vertical direction, of the floating diffusion region.

2. The image sensor of claim 1,
wherein a material of the first blocking layer is an insulating material.

3. The image sensor of claim 2,
wherein the insulating material of the first blocking layer includes silicon oxide.

4. The image sensor of claim 1,
wherein the first blocking layer is positioned inside the substrate and below the floating diffusion region.

5. The image sensor of claim 4, further comprising:
a shallow trench formed at the first surface of the substrate; and
a shallow trench isolation pattern positioned inside the shallow trench,
wherein a maximum depth, in the vertical direction, of the first blocking layer from the first surface is substantially equal to or smaller than a depth, in the vertical direction, of the shallow trench.

6. The image sensor of claim 5, further comprising:
a plurality of active regions that are defined by the shallow trench isolation pattern,
wherein the floating diffusion region is connected to the plurality of active regions.

7. The image sensor of claim 6, further comprising:
a plurality of second blocking layers that are positioned below the plurality of active regions inside the substrate, respectively.

8. The image sensor of claim 7,
wherein a maximum depth, in the vertical direction, of the plurality of second blocking layers from the first surface is substantially equal to or smaller than the depth, in the vertical direction, of the shallow trench.

9. The image sensor of claim 7, further comprising:
a plurality of gate electrodes positioned on the first surface of the substrate,
wherein the plurality of gate electrodes overlap the plurality of active regions in the vertical direction, and
wherein the plurality of second blocking layers are positioned below the plurality of gate electrodes, respectively.

10. An image sensor comprising:
a substrate that includes a first surface and a second surface facing each other;
a plurality of photoelectric conversion elements that are positioned inside the substrate;
a floating diffusion region that is adjacent to the first surface and inside the substrate, wherein the floating diffusion region is doped with an impurity; and
a first blocking layer positioned in a space between the floating diffusion region and each of the plurality of photoelectric conversion elements in a vertical direction perpendicular to the first surface of the substrate,
wherein a thickness, in the vertical direction, of the first blocking layer is substantially equal to or larger than a thickness, in the vertical direction, of the floating diffusion region,
wherein the floating diffusion region includes a lower floating diffusion region in the substrate,
wherein the first blocking layer extends through the lower floating diffusion region of the floating diffusion region from the first surface of the substrate toward the second surface of the substrate so that a bottom surface of the first blocking layer is lower than a bottom surface of the lower floating diffusion region of the floating diffusion region, and
wherein the lower floating diffusion region contacts a side surface of the first blocking layer.

11. The image sensor of claim 10,
wherein the floating diffusion region further includes an upper floating diffusion region that is positioned on a top surface of the first blocking layer, and
wherein the upper floating diffusion region of the floating diffusion region contacts the lower floating diffusion region of the floating diffusion region.

12. The image sensor of claim 11,
wherein the upper floating diffusion region includes an overlapping portion that is positioned on the lower floating diffusion region in the vertical direction, and
wherein the overlapping portion of the upper floating diffusion region contacts the lower floating diffusion region.

13. The image sensor of claim 12,
wherein a width, in a horizontal direction parallel to the first surface of the substrate, of the overlapping portion is narrower than a width, in the horizontal direction, of the lower floating diffusion region.

14. The image sensor of claim 11,
wherein the upper floating diffusion region contains crystalline silicon doped with the impurity.

15. The image sensor of claim 11,
wherein the first blocking layer and the upper floating diffusion region overlap a region surrounded by the plurality of photoelectric conversion elements in the vertical direction.

16. The image sensor of claim 11, further comprising:
a shallow trench formed at the first surface of the substrate; and
a shallow trench isolation pattern positioned inside the shallow trench,
wherein a maximum depth, in the vertical direction, of the first blocking layer from the first surface is substantially equal to or smaller than a depth, in the vertical direction, of the shallow trench.

17. The image sensor of claim 16, further comprising:
a plurality of active regions that are defined by the shallow trench isolation pattern,
wherein the floating diffusion region is connected to the plurality of active regions.

18. The image sensor of claim 17, further comprising:
a plurality of second blocking layers that are positioned below the plurality of active regions inside the substrate, respectively.

19. The image sensor of claim 18,
wherein a maximum depth, in the vertical direction, of the plurality of second blocking layers is substantially equal to or smaller than a depth, in the vertical direction, of the shallow trench.

20. The image sensor of claim 19, further comprising:
a plurality of gate electrodes positioned on the first surface of the substrate,
wherein the plurality of gate electrodes overlap the plurality of active regions in the vertical direction, and
wherein the plurality of second blocking layers are positioned below the plurality of gate electrodes, respectively.
